(19) United States
(12) Patent Application Publication
(10) Pub. No.: US 2025/0167676 A1
(43) Pub. Date: May 22, 2025

(54) DCDC CONVERTER MODULE

(71) Applicant: Murata Manufacturing Co., Ltd., Nagaokakyo-shi (JP)

(72) Inventors: Koshi HIMEDA, Nagaokakyo-shi (JP); Kazuki ITOYAMA, Nagaokakyo-shi (JP); Kenji NISHIYAMA, Nagaokakyo-shi (JP); Akitomo TAKAHASHI, Nagaokakyo-shi (JP); Nobuyoshi ADACHI, Nagaokakyo-shi (JP)

(21) Appl. No.: 19/027,470

(22) Filed: Jan. 17, 2025

Related U.S. Application Data
(63) Continuation of application No. PCT/JP2024/010460, filed on Mar. 18, 2024.

(30) Foreign Application Priority Data
Apr. 19, 2023 (JP) 2023-068577

(51) Int. Cl. H02M 3/00; H02M 1/44

(52) U.S. Cl. CPC H02M 3/003; H02M 1/44

(57) ABSTRACT

A DCDC converter module is provided that includes an insulating substrate having first and second surfaces; and a circuit section at the insulating substrate. The circuit section includes a switching element and an output filter connected to the switching element in series from an input end to an output. The output filter has an output inductor, and first and second output capacitors connected in parallel to each other and having different capacitance. A current path from the switching element to the output end of the circuit section penetrates through the insulating substrate from the first surface to the second surface. The first and second output capacitors are different from each other in position in a thickness direction and are arranged to the current path. An inductor component is between a plus terminal of the first output capacitor and a plus terminal of the second output capacitor.

### CROSS REFERENCE TO RELATED APPLICATIONS

This application is a continuation of International Application No. PCT/JP2024/010460, filed Mar. 18, 2024, which claims priority to Japanese Patent Application No. 2023-068577, filed Apr. 19, 2023, the contents of each of which are hereby incorporated by reference in their entirety.

### TECHNICAL FIELD

The present invention relates to DCDC converter modules.

### BACKGROUND

A current example of a DCDC converter module, a voltage regulator module including a circuit board assembly and a magnetic core assembly is disclosed in U.S. Patent Application Publication No. 2020/0111597.

In the DCDC converter module disclosed therein, in preparation for when the output voltage fluctuates due to abrupt fluctuations in load current, many output capacitors may be arranged to reduce output impedance. However, in the DCDC converter module, if many output capacitors are arranged on the same plane as in the structure shown therein, the module area in plan view increases.

### SUMMARY OF THE INVENTION

In view of the above-described problem, it is an object of the present disclosure to provide a DCDC converter module configured to reduce an output impedance while saving the module area.

In an exemplary aspect, a DCDC converter module is provided that includes an insulating substrate having a first surface and a second surface opposing each other in a thickness direction; and a circuit section provided to the insulating substrate. The circuit section includes a switching element and an LC-chopper-type output filter connected to the switching element, in order from an input end toward an output end. The output filter has an output inductor, a first output capacitor connected in series to the output inductor on an output end side of the circuit section, and a second output capacitor connected in series to the output inductor on the output end side of the circuit section and connected in parallel to the first output capacitor at a position closer to the output end side of the circuit section than the first output capacitor. In this aspect, the second output capacitor has a capacitance different from a capacitance of the first output capacitor. A current path from the switching element to the output end of the circuit section penetrates through the insulating substrate from the first surface to the second surface. Moreover, the first output capacitor and the second output capacitor are different from each other in position in the thickness direction on arrangement surfaces where the first output capacitor and the second output capacitor are arranged to the current path. An inductor component is disposed between a plus terminal of the first output capacitor and a plus terminal of the second output capacitor.

According to the exemplary aspects of the present disclosure, a DCDC converter module is provided that is configured for reducing output impedance while saving the module area.

### BRIEF DESCRIPTION OF DRAWINGS

FIG. 1 is a circuit structure diagram illustrating an exemplary circuit structure of a DCDC converter module of the present disclosure.

FIG. 2 is a sectional schematic view illustrating an exemplary DCDC converter module of a first embodiment of the present disclosure.

FIG. 3 is a sectional schematic view illustrating an exemplary DCDC converter module of a second embodiment of the present disclosure.

FIG. 4 is a sectional schematic view illustrating an exemplary DCDC converter module of a third embodiment of the present disclosure.

FIG. 5 is a sectional schematic view illustrating an exemplary DCDC converter module of a fourth embodiment of the present disclosure.

FIG. 6 is a sectional schematic view illustrating an exemplary DCDC converter module of a fifth embodiment of the present disclosure.

FIG. 7 is a graph indicating a relation between a reduction ratio of output impedance and frequency of the DCDC converter module of a first example with respect to a DCDC converter module of a first comparative example.

### DETAILED DESCRIPTION OF EMBODIMENTS

The DCDC converter module of the present disclosure is described below. It is noted that the exemplary embodiments are not limited to the following structure and may be changed as appropriate in a range not deviating from the gist of the present disclosure. Also, exemplary embodiments obtained by combining a plurality of individual preferable structures described below is also included in the present disclosure.

The drawings described below are schematic diagrams, and dimensions, aspect-ratio scale, and so forth in the drawings may be different from those of an actual product.

In the specification and present disclosure, unless otherwise specified, terms indicating a relation between elements (for example, “perpendicular”, “parallel”, or the like) and terms indicating the shape of an element each mean not only a literally strict mode, but also a substantially equivalent range, for example, a range including a difference on the order of several percent, which takes into account manufacturing tolerances, for example.

In an exemplary aspect, a DCDC converter module according to the present disclosure includes an insulating substrate having a first surface and a second surface opposing each other in a thickness direction; and a circuit section provided to (e.g., on or at) the insulating substrate. The circuit section includes a switching element and an LC-chopper-type output filter connected to the switching element, in order from an input end toward an output end. The output filter has an output inductor, a first output capacitor connected in series to the output inductor on an output end side of the circuit section, and a second output capacitor connected in series to the output inductor on the output end side of the circuit section and connected in parallel to the first output capacitor at a position closer to the output end side of the circuit section than the first output capacitor. In this aspect, the second output capacitor has a capacitance different from a capacitance of the first output capacitor. A current path from the switching element to the output end of the circuit section penetrates through the insulating substrate from the first surface to the second surface. The first output capacitor and the second output capacitor are different from each other in position in the thickness direction on arrangement surfaces where the first output capacitor and the second output capacitors are arranged to the current path. Moreover, an inductor component is between a plus terminal of the first output capacitor and a plus terminal of the second output capacitor.

In the following, an example of circuit structure of the DCDC converter module of the present disclosure is described.

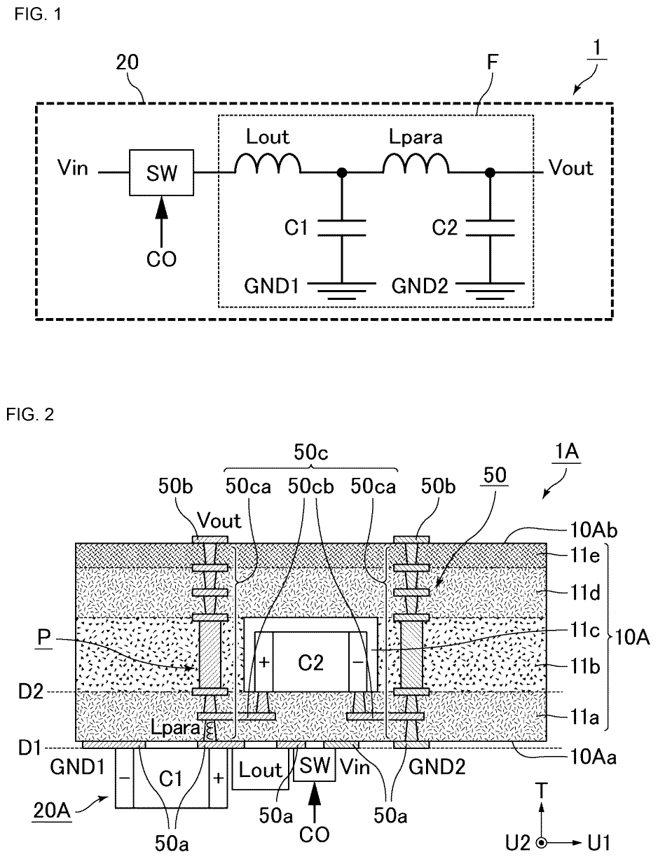

FIG. 1 is a circuit structure diagram illustrating an exemplary circuit structure of the DCDC converter module of the present disclosure.

A DCDC converter module 1 depicted in FIG. 1 has a circuit section 20.

As shown, the circuit section 20 has a switching element SW and an LC-chopper-type output filter F, connected in series in the order from an input end Vin toward an output end Vout.

The switching element SW has an input side connected to the input end Vin of the circuit section 20.

The timing of switching by the switching element SW is controlled by a control signal received from a controller CO according to an exemplary aspect.

The output filter F is connected to the switching element SW. Specifically, the output filter F is connected to the switching element SW on an output end Vout side of the circuit section 20.

The output filter F has an output inductor Lout, a first output capacitor C1, and a second output capacitor C2.

The output inductor Lout is connected in series to the switching element SW on the output end Vout side of the circuit section 20.

The first output capacitor C1 is connected in series to the output inductor Lout on the output end Vout side of the circuit section 20. Specifically, the first output capacitor C1 has a plus (+) terminal side connected to the output inductor Lout and a minus (−) terminal side connected to a first ground end GND1.

The second output capacitor C2 is connected in series to the output inductor Lout on the output end Vout side of the circuit section 20. Specifically, the second output capacitor C2 has a plus (+) terminal side connected to the output inductor Lout and a minus (−) terminal side connected to a second ground end GND2.

The second output capacitor C2 is connected in parallel to the first output capacitor C1 at a position closer to the output end Vout side of the circuit section 20 than the first output capacitor C1.

In an exemplary aspect, the second output capacitor C2 has a capacitance that is different from a capacitance of the first output capacitor C1.

The capacitance of the second output capacitor C2 may be larger than the capacitance of the first output capacitor C1 or may be smaller than the capacitance of the first output capacitor C1 in various exemplary aspects.

As further shown, an inductor component Lpara is between the plus terminal of the first output capacitor C1 and the plus terminal of the second output capacitor C2. Specifically, the inductor component Lpara is disposed between a contact point between the plus terminal of the first output capacitor C1 and the output inductor Lout and a contact point between the plus terminal of the second output capacitor C2 and the output end Vout of the circuit section 20.

The output end Vout of the circuit section 20 is connected to a load (not shown). With this configuration, a direct-current voltage adjusted by the DCDC converter module 1 can be supplied to the load.

As a load, for example, a semiconductor integrated circuit (IC), such as a logical operation circuit or a storage circuit, or the like can be provided.

In the following, an example of structure of the DCDC converter module of the present disclosure is described according to various exemplary embodiments.

Each embodiment described below is an example, and it is needless to say that partial replacement or combination of structures described in different embodiments can be made as would be appreciated to one skilled in the art. Moreover, in a second embodiment onward, description common to a first embodiment is omitted, and a different point is mainly described. In particular, each similar operation and effect by a similar structure is not mentioned for each embodiment.

In the following description, when each embodiment is not particularly distinguished from the other, the disclosure is simply referred to as the “DCDC converter module of the present disclosure”.

### First Exemplary Embodiment

In a DCDC converter module of the first embodiment of the present disclosure, one of a first output capacitor and a second output capacitor is provided inside an insulating substrate.

FIG. 2 is a sectional schematic view illustrating an exemplary DCDC converter module of the first embodiment of the present disclosure.

As shown, a DCDC converter module 1A depicted in FIG. 2 has an insulating substrate 10A and a circuit section 20A.

The insulating substrate 10A has a first surface 10Aa and a second surface 10Ab that oppose each other in a thickness direction T.

The insulating substrate 10A is configured of at least one insulating layer. That is, the insulating substrate 10A may be configured of one insulating layer or may be configured of a plurality of insulating layers in various exemplary aspects.

In an example depicted in FIG. 2, the insulating substrate 10A is configured of an insulating layer 11a, an insulating layer 11b, an insulating layer 11c, an insulating layer 11d, and an insulating layer 11e. In each space between insulating layers, an interface may be clearly present as depicted in FIG. 2 or does not have to be clearly present in alternative aspects.

An insulating material configuring the insulating substrate 10A may contain an insulating resin, for example.

As an insulating resin contained in the insulating material configuring the insulating substrate 10A, for example, an epoxy resin, a polyester resin, a bismaleimide-triazine resin, a polyimide resin, a phenol resin, an allylated phenylene ether resin, or the like can be provided.

When the insulating substrate 10A is configured by a plurality of insulating layers, the insulating materials configuring the plurality of insulating layers may be identical to one another, different from one another, or partially different according to various exemplary aspects.

As further shown, the circuit section 20A is provided to (e.g., disposed at or coupled to) the insulating substrate 10A.

More particularly, example configurations of the circuit section 20A including disposing the circuit section 20A inside the insulating substrate 10A and disposing the circuit section 20A on a surface of the insulating substrate 10A.

As further shown, an input end Vin, a switching element SW, an output inductor Lout, a first output capacitor C1, a first ground end GND1, and a second ground end GND2 of the circuit section 20A are provided on the first surface 10Aa of the insulating substrate 10A.

Moreover, an output end Vout of the circuit section 20A is provided on the second surface 10Ab of the insulating substrate 10A.

A second output capacitor C2 of the circuit section 20A is inside the insulating substrate 10A. Specifically, the second output capacitor C2 is provided inside the insulating layer 11c in the exemplary embodiment.

In the example depicted in FIG. 2, the switching element SW and the output end Vout of the circuit section 20A do not overlap when viewed from the thickness direction T, but the switching element SW and the output end Vout of the circuit section 20A may overlap at least partially when viewed from the thickness direction T in another exemplary aspect. In this case, when viewed from the thickness direction T, the switching element SW easily overlaps a load (not shown) connected to the output end Vout of the circuit section 20A, and therefore the size of the DCDC converter module 1A when it is connected to the load can be easily decreased.

In the circuit section 20A, the input end Vin, the switching element SW, the output inductor Lout, the first output capacitor C1, the second output capacitor C2, the first ground end GND1, the second ground end GND2, and the output end Vout are connected to one another via a conductor 50.

The conductor 50 includes a first surface conductor 50a, a second surface conductor 50b, and an inner conductor 50c.

The first surface conductor 50a is provided on the first surface 10Aa of the insulating substrate 10A.

The second surface conductor 50b is provided on the second surface 10Ab of the insulating substrate 10A.

The inner conductor 50c is provided inside the insulating substrate 10A and is connected to the first surface conductor 50a and the second surface conductor 50b. That is, the first surface conductor 50a and the second surface conductor 50b are connected together via the inner conductor 50c.

The inner conductor 50c includes a through conductor 50ca penetrating through the insulating substrate 10A in the thickness direction T.

The inner conductor 50c may further include a branch conductor 50cb branching from the through conductor 50ca to extend to a surface direction perpendicular to the thickness direction T. The surface direction is a direction including a first direction U1 perpendicular to the thickness direction T and a second direction U2 perpendicular to the thickness direction T and the first direction U1.

As a conductive material configuring the conductor 50, for example, a metal material containing a low-resistant metal such as copper, gold, or silver; a composite material of the above-described metal and resin; or the like can be provided.

In the DCDC converter module 1A, a current path P from the switching element SW to the output end Vout of the circuit section 20A penetrates through the insulating substrate 10A from the first surface 10Aa to the second surface 10Ab. Specifically, in the DCDC converter module 1A, the current path P passes through the conductor 50 and, of that path, a path passing through the inner conductor 50c, for example, a path passing through the through conductor 50ca, penetrates through the insulating substrate 10A from the first surface 10Aa to the second surface 10Ab.

In the DCDC converter module 1A, the current path P passes through the outside of the second output capacitor C2.

In the DCDC converter module 1A, the first output capacitor C1 and the second output capacitor C2 are different from each other in position in the thickness direction T on arrangement surfaces where the first output capacitor C1 and the second output capacitor C2 are arranged to the current path P.

In the DCDC converter module 1A, the position of an arrangement surface D1 of the first output capacitor C1 arranged to the current path P is defined by a position of an interface between the first output capacitor C1 and the first surface conductor 50a. That is, in the DCDC converter module 1A, the arrangement surface D1 of the first output capacitor C1 is disposed outside the insulating substrate 10A, here, at a position opposite to the second surface 10Ab with respect to the first surface 10Aa of the insulating substrate 10A.

In the DCDC converter module 1A, the position of an arrangement surface D2 of the second output capacitor C2 arranged to the current path P is defined by a position of an interface between the second output capacitor C2 and the inner conductor 50c, here, a position identical to an interface between the insulating layer 11a and the insulating layer 11b or an interface between the insulating layer 11a and the insulating layer 11c. That is, in the DCDC converter module 1A, the arrangement surface D2 of the second output capacitor C2 is disposed inside the insulating substrate 10.

As described above, in the DCDC converter module 1A, the position of the arrangement surface D1 of the first output capacitor C1 and the position of the arrangement surface D2 of the second output capacitor C2 are different from each other in the thickness direction T.

In the DCDC converter module 1A, with the position of the arrangement surface D1 of the first output capacitor C1 and the position of the arrangement surface D2 of the second output capacitor C2 arranged to the current path P penetrating through the insulating substrate 10A from the first surface 10Aa to the second surface 10Ab being different from each other in the thickness direction T, the first output capacitor C1 and the second output capacitor C2 are not arranged on the same plane. As a result, a module area for arranging the first output capacitor C1 and the second output capacitor C2 can be eliminated. Specifically, in the DCDC converter module 1A, since the second output capacitor C2 is provided inside the insulating substrate 10A, a module area for arranging the second output capacitor C2 on a surface of the insulating substrate 10A is not required.

In the DCDC converter module 1A, an inductor component Lpara is provided between a plus terminal of the first output capacitor C1 and a plus terminal of the second output capacitor C2.

In the DCDC converter module 1A, the inductor component Lpara is configured of the conductor 50 that connects between the plus terminal of the first output capacitor C1 and the plus terminal of the second output capacitor C2, here, part of the inner conductor 50c.

It is noted that the inductor component Lpara does not have to be configured of the conductor 50 that connects between the plus terminal of the first output capacitor C1 and the plus terminal of the second output capacitor C2, but may be an inductor element (e.g., n inductor or inductor component) that connects between the plus terminal of the first output capacitor C1 and the plus terminal of the second output capacitor C2.

In the DCDC converter module 1A, output impedance can be reduced due to the inductor component Lpara. Thus, in the DCDC converter module 1A, fluctuations of output voltage due to abrupt fluctuations of the load current can be suppressed or minimized.

In the DCDC converter module 1A, even if many output capacitors are not arranged, for example, if only the first output capacitor C1 and the second output capacitor C2 are provided, output impedance can still be reduced. In this manner, in the DCDC converter module 1A, it is not required to arrange many output capacitors to reduce output impedance, and therefore the module area can be saved.

From above exemplary aspect, according to the DCDC converter module 1A, a DCDC converter module is provided that is configured for reduced output impedance while the module area is saved.

In an exemplary aspect, the inductance of the inductor component Lpara is preferably smaller than the inductance of the output inductor Lout.

In the above, in the DCDC converter module of the present disclosure, a mode is exemplarily described in which the second output capacitor (and not the first output capacitor) is inside the insulating substrate. However, in place of the second output capacitor, the first output capacitor may be provided inside the insulating substrate in an alternative aspect.

### Second Exemplary Embodiment

In a DCDC converter module of the second embodiment of the present disclosure, a first output capacitor and a second output capacitor are both provided inside an insulating substrate.

In particular, the DCDC converter module of the second embodiment of the present disclosure is similar to the DCDC converter module of the first embodiment of the present disclosure except the above-described feature.

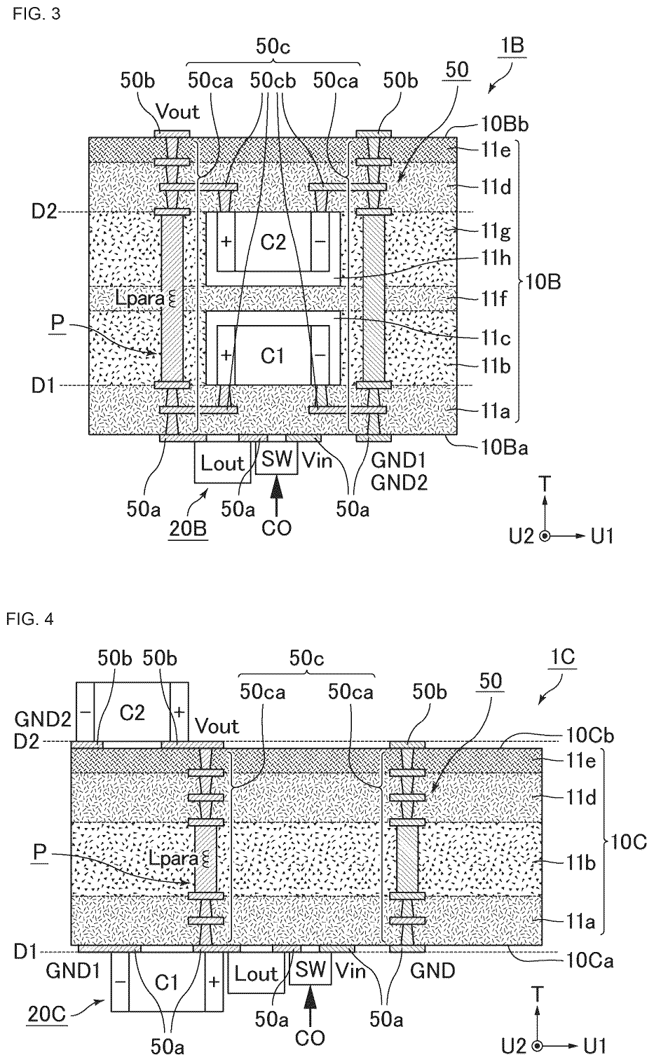

FIG. 3 is a sectional schematic view illustrating an exemplary DCDC converter module of the second embodiment of the present disclosure.

A DCDC converter module 1B depicted in FIG. 3 has an insulating substrate 10B and a circuit section 20B.

The insulating substrate 10B has a first surface 10Ba and a second surface 10Bb that oppose each other in a thickness direction T.

The insulating substrate 10B is configured of an insulating layer 11a, an insulating layer 11b, an insulating layer 11c, an insulating layer 11d, an insulating layer 11e, an insulating layer 11f, an insulating layer 11g, and an insulating layer 11h.

An input end Vin, a switching element SW, an output inductor Lout, a first ground end GND1, and a second ground end GND2 of the circuit section 20B are disposed on the first surface 10Ba of the insulating substrate 10B.

An output end Vout of the circuit section 20B is disposed on the second surface 10Bb of the insulating substrate 10B.

As noted above, a first output capacitor C1 and a second output capacitor C2 of the circuit section 20B are both provided inside the insulating substrate 10B. Specifically, the first output capacitor C1 is provided inside the insulating layer 11c, and the second output capacitor C2 is provided inside the insulating layer 11h.

In the DCDC converter module 1B, an arrangement surface D1 of the first output capacitor C1 arranged to a current path P is dispose inside the insulating substrate 10.

In the DCDC converter module 1B, an arrangement surface D2 of the second output capacitor C2 arranged to the current path P is present inside the insulating substrate 10 and at a position different from the arrangement surface D1 of the first output capacitor C1 in the thickness direction T.

In the DCDC converter module 1B, since the first output capacitor C1 and the second output capacitor C2 are provided inside the insulating substrate 10B, for example, compared with the DCDC converter module 1A (refer to FIG. 2), a module area for arranging the first output capacitor C1 on a surface of the insulating substrate is eliminated. Thus, in the DCDC converter module 1B, compared with the DCDC converter module 1A, the module area is further reduced.

In view of saving the module area, as depicted in FIG. 3, the first output capacitor C1 and the second output capacitor C2 preferably at least partially overlap each other when viewed from the thickness direction T, and more preferably, entirely overlap each other when viewed from the thickness direction T.

Also in other exemplary embodiments, the first output capacitor C1 and the second output capacitor C2 preferably at least partially overlap each other when viewed from the thickness direction T.

### Third Exemplary Embodiment

In a DCDC converter module of a third embodiment of the present disclosure, a first output capacitor is provided on one of a first surface and a second surface of an insulating substrate, and a second output capacitor is provided on the other one of the first surface and the second surface of the insulating substrate.

The DCDC converter module of the third embodiment of the present disclosure is similar to the DCDC converter module of the first embodiment of the present disclosure except the above-described feature.

FIG. 4 is a sectional schematic view illustrating an exemplary DCDC converter module of the third embodiment of the present disclosure.

As shown, a DCDC converter module 1C depicted in FIG. 4 has an insulating substrate 10C and a circuit section 20C.

The insulating substrate 10C has a first surface 10Ca and a second surface 10Cb that oppose each other in a thickness direction T.

The insulating substrate 10C is configured of an insulating layer 11a, an insulating layer 11b, an insulating layer 11d, and an insulating layer 11e.

An input end Vin, a switching element SW, an output inductor Lout, a first output capacitor C1, and a first ground end GND1 of the circuit section 20C are disposed on the first surface 10Ca of the insulating substrate 10C.

A second output capacitor C2, a second ground end GND2, and an output end Vout of the circuit section 20C are disposed on the second surface 10Cb of the insulating substrate 10C.

In the DCDC converter module 1C, an arrangement surface D1 of the first output capacitor C1 arranged to a current path P is outside the insulating substrate 10C, here, at a position opposite to the second surface 10Cb with respect to the first surface 10Ca of the insulating substrate 10C.

In the DCDC converter module 1C, an arrangement surface D2 of the second output capacitor C2 arranged to the current path P is disposed outside the insulating substrate 10C and at a position different from the arrangement surface D1 of the first output capacitor C1 in the thickness direction T, here, at a position opposite to the first surface 10Ca with respect to the second surface 10Cb of the insulating substrate 10C.

In the DCDC converter module 1C, with the first output capacitor C1 provided on the first surface 10Ca of the insulating substrate 10C and the second output capacitor C2 provided on the second surface 10Cb of the insulating substrate 10C, for example, compared with the DCDC converter module 1A (refer to FIG. 2), a process of providing the output capacitors inside the insulating substrate in the course of manufacture can be eliminating. Thus, in the DCDC converter module 1C, compared with the DCDC converter module 1A, manufacturing efficiency is improved.

In the above, in the DCDC converter module of the present disclosure, the mode is exemplarily described in which the first output capacitor is provided on the first surface of the insulating substrate and the second output capacitor is provided on the second surface of the insulating substrate. However, the first output capacitor may be provided on the second surface of the insulating substrate and the second output capacitor may be provided on the first surface of the insulating substrate in an alternative aspect.

### Fourth Exemplary Embodiment

In a DCDC converter module of a fourth embodiment of the present disclosure, a magnetic material is present in at least part of surroundings of a conductor connecting between a plus terminal of a first output capacitor and a plus terminal of a second output capacitor.

The DCDC converter module of the fourth embodiment of the present disclosure is similar to the DCDC converter modules of the first to third embodiments of the present disclosure except the above-described feature.

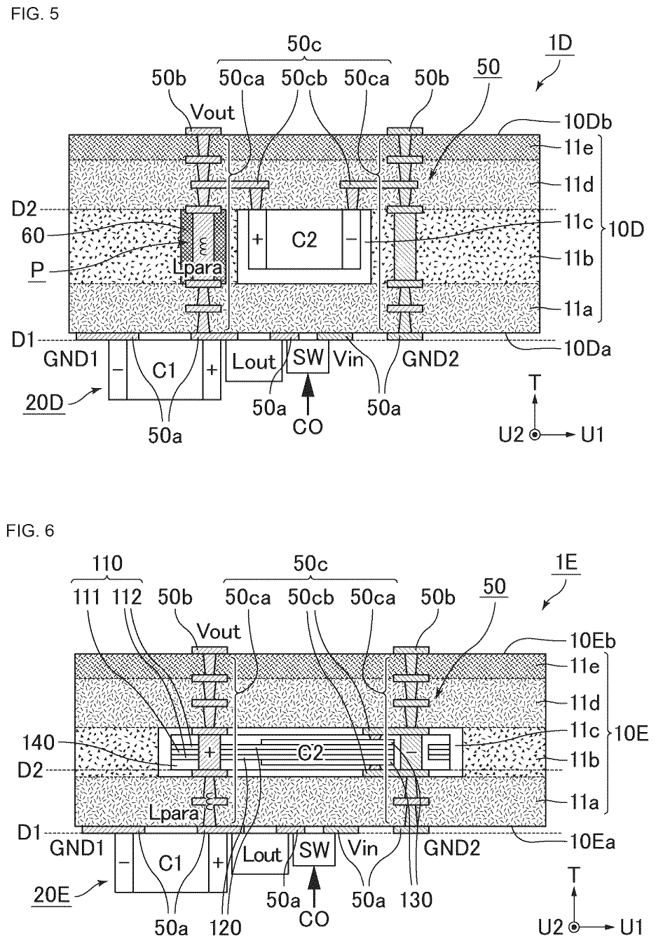

FIG. 5 is a sectional schematic view illustrating an exemplary DCDC converter module of the fourth embodiment of the present disclosure.

As shown, a DCDC converter module 1D depicted in FIG. 5 has an insulating substrate 10D and a circuit section 20D.

The insulating substrate 10D has a first surface 10Da and a second surface 10Db that oppose each other in a thickness direction T.

The insulating substrate 10D is configured of an insulating layer 11a, an insulating layer 11b, an insulating layer 11c, an insulating layer 11d, and an insulating layer 11e.

An input end Vin, a switching element SW, an output inductor Lout, a first output capacitor C1, a first ground end GND1, and a second ground end GND2 of the circuit section 20D are disposed on the first surface 10Da of the insulating substrate 10D.

An output end Vout of the circuit section 20D is disposed on the second surface 10Db of the insulating substrate 10D.

A second output capacitor C2 of the circuit section 20D is provided inside the insulating substrate 10D. Specifically, the second output capacitor C2 is provided inside the insulating layer 11c.

In the DCDC converter module 1D, a magnetic material 60 is present in at least part of surroundings of a conductor 50 connecting between a plus terminal of the first output capacitor C1 and a plus terminal of the second output capacitor C2. Specifically, in the DCDC converter module 1D, of an inner conductor 50c connecting between the plus terminal of the first output capacitor C1 and the plus terminal of the second output capacitor C2, the magnetic material 60 provided inside the insulating layer 11b is present in at least part of the surroundings of a through conductor 50ca penetrating through the insulating layer 11b in the thickness direction T.

In the DCDC converter module 1D, with an inductor component Lpara configured of the conductor 50 connecting between the plus terminal of the first output capacitor C1 and the plus terminal of the second output capacitor C2 and the magnetic material 60 that is present in at least part of the surroundings of the conductor 50, for example, compared with the DCDC converter module 1A (refer to FIG. 2), the inductance of the inductor component Lpara is increased, and thus output impedance can be further reduced. In this manner, in the DCDC converter module 1D, it is not required to arrange many output capacitors to further reduce output impedance, and therefore the module area can be further reduced.

In view of increasing the inductance of the inductor component Lpara, the magnetic material 60 is preferably present over the entire perimeter of the conductor 50 connecting between the plus terminal of the first output capacitor C1 and the plus terminal of the second output capacitor C2.

It is noted that the magnetic material 60 the magnetic material 60 may be present in part of the surroundings of the conductor 50 connecting between the plus terminal of the first output capacitor C1 and the plus terminal of the second output capacitor C2.

In view of increasing the inductance of the inductor component Lpara, the magnetic material 60 is preferably in contact with the conductor 50 connecting between the plus terminal of the first output capacitor C1 and the plus terminal of the second output capacitor C2.

### Fifth Exemplary Embodiment

In a DCDC converter module of a fifth embodiment of the present disclosure, a current path penetrates (e.g., extends) inside a second output capacitor.

The DCDC converter module of the fifth embodiment of the present disclosure is similar to the DCDC converter modules of the first to fourth embodiments of the present disclosure except the above-described feature.

FIG. 6 is a sectional schematic view illustrating an exemplary DCDC converter module of the fifth embodiment of the present disclosure.

A DCDC converter module 1E depicted in FIG. 6 has an insulating substrate 10E and a circuit section 20E.

The insulating substrate 10E has a first surface 10Ea and a second surface 10Eb opposed to each other in a thickness direction T.

The insulating substrate 10E is configured of an insulating layer 11a, an insulating layer 11b, an insulating layer 11c, an insulating layer 11d, and an insulating layer 11e.

An input end Vin, a switching element SW, an output inductor Lout, a first output capacitor C1, a first ground end GND1, and a second ground end GND2 of the circuit section 20E are disposed on the first surface 10Ea of the insulating substrate 10E.

An output end Vout of the circuit section 20E is disposed on the second surface 10Eb of the insulating substrate 10E.

A second output capacitor C2 of the circuit section 20E is provided inside the insulating substrate 10E. Specifically, the second output capacitor C2 is provided inside the insulating layer 11c.

In the DCDC converter module 1E, a current path P penetrates inside the second output capacitor C2. With this configuration, in the DCDC converter module 1E, for example, compared with the DCDC converter module 1A (refer to FIG. 2), an arrangement region of an insulating layer that is present between the current path P and the second output capacitor C2 in a surface direction can be saved, and therefore the module area can be further reduced.

The mode in which the current path P penetrates inside the second output capacitor C2 is achieved when, for example, the second output capacitor C2 is an electrolytic capacitor having a structure as described below.

In an example depicted in FIG. 6, the second output capacitor C2 has an anode layer 110, a dielectric layer 120, and a cathode layer 130.

The anode layer 110 has a core portion 111 and a porous portion 112.

The core portion 111 is preferably configured of a metal, and is, among others, preferably configured of a valve-action metal. When the core portion 111 is configured of a valve-action metal, the anode layer 110 is also called a valve-action metal base body.

As a valve-action metal configuring the core portion 111, for example, an elemental metal such as aluminum, tantalum, niobium, titanium, or zirconium; an alloy containing at least one type of these elemental metals; or the like can be provided in exemplary aspects.

The porous portion 112 is provided on at least one surface of both surfaces of the core portion 111 opposed in the thickness direction T. That is, the porous portion 112 may be provided on only one surface of the core portion 111 or may be provided on both surfaces of the core portion 111. In this manner, the anode layer 110 has the porous portion 112 on at least one surface of both surfaces opposed in the thickness direction T.

The porous portion 112 is preferably an etching layer formed by etching a surface of the anode layer 110 (core portion 111).

The shape of the anode layer 110 is preferably a flat plate shape (anode plate), and more preferably a foil shape (anode foil).

The dielectric layer 120 is provided on a surface of the porous portion 112. Specifically, the dielectric layer 120 is provided along a surface (contour) of each pore that is present in the porous portion 112.

The dielectric layer 120 is preferably formed of an oxide film of the above-described valve-action metal. For example, when the anode layer 110 is an aluminum foil, anodizing process (also called forming process) is performed on the aluminum foil in an aqueous solution containing ammonium adipate or the like, and thus an oxide film serving as the dielectric layer 120 is formed. Since the dielectric layer 120 is formed along the surface of the porous portion 112, pores (recessed portions) are provided in the dielectric layer 120.

As further shown, the cathode layer 130 faces the anode layer 110 via the dielectric layer 120 in the thickness direction T.

The cathode layer 130 is provided on a surface of the dielectric layer 120.

The cathode layer 130 preferably has a solid electrolyte layer (not shown) provided on the surface of the dielectric layer 120 and a conductive layer (not shown) provided on a surface of the solid electrolyte layer. When the cathode layer 130 has a solid electrolyte layer, the second output capacitor C2 configures a solid electrolyte capacitor.

In the example depicted in FIG. 6, the second output capacitor C2 may further include a sealing layer 140 that seals a capacitor body configured of the anode layer 110, the dielectric layer 120, and the cathode layer 130.

As for the structure of the second output capacitor C2 depicted FIG. 6 other than the above, for example, the capacitor layer described in International Publication No. 2021/241325 can be considered and is hereby incorporated by reference.

With respect to the second output capacitor C2 having the structure described above, a through conductor 50ca (in FIG. 6, through conductor 50ca on the left) connecting between a first surface conductor 50a connected to a plus terminal of the first output capacitor C1 and a second surface conductor 50b connected to the output end Vout of the circuit section 20E penetrates through the second output capacitor C2 in the thickness direction T and is also connected to the anode layer 110. With this, the through conductor 50ca connected to the anode layer 110 functions as a plus terminal of the second output capacitor C2.

With respect to the second output capacitor C2 having the structure described above, a through conductor 50ca (in FIG. 6, through conductor 50ca on the right) connecting between the first surface conductor 50a connected to the second ground end GND2 of the circuit section 20E and the second surface conductor 50b penetrates through the second output capacitor C2 in the thickness direction T and is also connected to the cathode layer 130 via a branch conductor 50cb. With this configuration, the through conductor 50ca connected to the cathode layer 130 functions as a minus terminal of the second output capacitor C2.

Having the structure as described above, the second output capacitor C2 can be made thinner. Thus, the DCDC converter module 1E having the second output capacitor C2 having the structure as described above can also be made thinner.

In the DCDC converter module of the present disclosure, in the above embodiments, as output capacitors, a mode is exemplarily described in which two output capacitors, that is, the first output capacitor and the second output capacitor, are provided. However, three or more output capacitors may be provided in alternative aspects. In this case, it is only required that, among three or more output capacitors, at least two output capacitors, that is, the first output capacitor and the second output capacitor, satisfy the features of the DCDC converter module of the present disclosure as described above. The output capacitors other than the first output capacitor and the second output capacitor preferably satisfy the features of the DCDC converter module of the present disclosure. Note that as long as the first output capacitor and the second output capacitor satisfy the features of the DCDC converter module of the present disclosure, the output capacitors other than the first output capacitor and the second output capacitor do not have to satisfy the features of the DCDC converter module of the present disclosure.

It is noted that in the DCDC converter module of the present disclosure, the type of output capacitor is not particularly limited and, for example, the above-described electrolytic capacitor, a ceramic capacitor using barium titanate, a thin-film capacitor using silicon nitride (SiN), silicon dioxide (SiO₂), hydrogen fluoride (HF), or the like, a trench-type capacitor having a metal insulator metal (MIM) structure, or the like may be used.

### EXAMPLES

In the following, examples specifically disclosing the DCDC converter module of the present disclosure are described. It is noted that the present disclosure is not limited only to the examples below.

### First Example

As a simulation model of a DCDC converter module of a first example, the structure of the DCDC converter module of the fifth embodiment described above was adopted.

### First Comparative Example

As a simulation model of a DCDC converter module of a first comparative example, the structure similar to that of the simulation model of the DCDC converter module of the first example except that the inductor component Lpara is not present was adopted.

### [Evaluation]

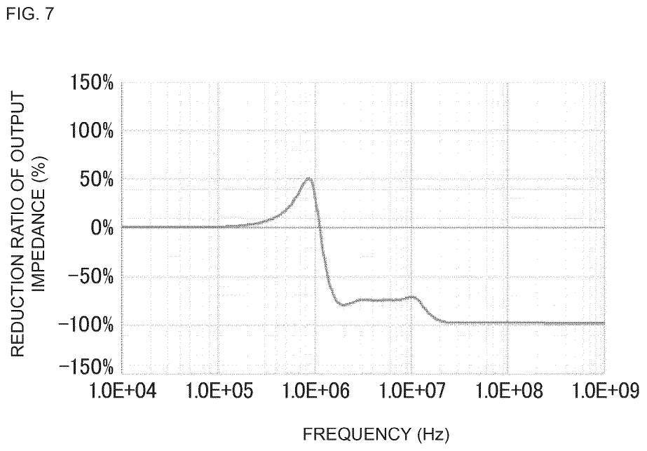

As for the DCDC converter modules of the first example and the first comparative example, simulation evaluation of frequency characteristics of output impedance was performed. Then, with output impedance of the DCDC converter module of the first example taken as Z1 and output impedance of the DCDC converter module of the first comparative example taken as Z2, a reduction ratio ΔZ of the output impedance of the DCDC converter module of the first example with respect to the DCDC converter module of the first comparative example was calculated as ΔZ=100×(Z1−Z2)/Z2. FIG. 7 is a graph indicating a relation between the reduction ratio of output impedance and frequency of the DCDC converter module of the first example with respect to the DCDC converter module of the first comparative example.

As depicted in FIG. 7, according to the DCDC converter module of the first example, compared with the DCDC converter module of the first comparative example, it was found that output impedance can be greatly reduced in a frequency band higher than 1 MHz. Therefore, it can be said that the DCDC converter module of the present disclosure is preferably used in a frequency band higher than 1 MHz.

In the specification, the following non-limiting exemplary aspects are disclosed.

<1> A DCDC converter module is provided that includes an insulating substrate having a first surface and a second surface that oppose each other in a thickness direction; and a circuit section provided to the insulating substrate. The circuit section includes a switching element and an LC-chopper-type output filter connected to the switching element in series from an input end to an output end. The output filter has an output inductor, a first output capacitor connected in series to the output inductor on an output end side of the circuit section, and a second output capacitor connected in series to the output inductor on the output end side of the circuit section and connected in parallel to the first output capacitor at a position closer to the output end side of the circuit section than the first output capacitor. The second output capacitor has a capacitance different a capacitance of the first output capacitor. Moreover, a current path from the switching element to the output end of the circuit section penetrates through the insulating substrate from the first surface to the second surface. The first output capacitor and the second output capacitor are different from each other in position in the thickness direction on arrangement surfaces where the first output capacitor and the second output capacitor are arranged to the current path. Finally, an inductor component is between a plus terminal of the first output capacitor and a plus terminal of the second output capacitor.

<2> The DCDC converter module according to <1>, in which one of the first output capacitor and the second output capacitor is inside the insulating substrate.

<3> The DCDC converter module according to <1>, in which the first output capacitor and the second output capacitor are both inside the insulating substrate.

<4> The DCDC converter module according to <1>, in which the first output capacitor is provided on one of the first surface and the second surface of the insulating substrate, and the second output capacitor is provided on another of the first surface and the second surface of the insulating substrate.

<5> The DCDC converter module according to any one of <1> to <4>, further comprising a magnetic material in at least part of surroundings of a conductor connecting between the plus terminal of the first output capacitor and the plus terminal of the second output capacitor.

<6> The DCDC converter module according to any one of <1> to <5>, in which the current path penetrates inside the second output capacitor.

<7> The DCDC converter module according to any one of <1> to <6>, in which inductance of the inductor component is smaller than inductance of the output inductor.

<8> The DCDC converter module according to any one of <1> to <7>, in which the first output capacitor and the second output capacitor at least partially overlap each other when viewed from the thickness direction.

### REFERENCE SIGNS LIST

1, 1A, 1B, 1C, 1D, 1E DCDC converter module
10A, 10B, 10C, 10D, 10E insulating substrate
10Aa, 10Ba, 10Ca, 10Da, 10Ea first surface of the insulating substrate
10Ab, 10Bb, 10Cb, 10Db, 10Eb second surface of the insulating substrate
11a, 11b, 11c, 11d, 11e, 11f, 11g, 11h insulating layer
20, 20A, 20B, 20C, 20D, 20E circuit section
50 conductor
50a first surface conductor
50b second surface conductor
50c inner conductor
50ca through conductor
50cb branch conductor
60 magnetic material
110 anode layer
111 core portion
112 porous portion
120 dielectric layer
130 cathode layer
140 sealing layer
C1 first output capacitor
C2 second output capacitor
CO controller
D1 arrangement surface of the first output capacitor
D2 arrangement surface of the second output capacitor
F output filter
GND1 first ground end
GND2 second ground end
Lout output inductor
Lpara inductor component
P current path
SW switching element
T thickness direction
U1 first direction
U2 second direction
Vin input end of the circuit section
Vout output end of the circuit section

What is claimed:

1. A DCDC converter module comprising:
an insulating substrate having a first surface and a second surface that oppose each other in a thickness direction; and
a circuit section that includes a switching element and an output filter connected to the switching element in series from an input end of the circuit section to an output end of the circuit section,
wherein the output filter has an output inductor, a first output capacitor connected in series to the output inductor and a second output capacitor connected in series to the output inductor and in parallel to the first output capacitor at a position closer to a side of the output end of the circuit section than the first output capacitor,
wherein a current path from the switching element to the output end of the circuit section extends through the insulating substrate from the first surface to the second surface,
wherein the first and second output capacitors are on respective arrangement surfaces for the current path and at a different positions from each other in the thickness direction, and
wherein an inductor component is between the first output capacitor and the second output capacitor.

2. The DCDC converter module according to claim 1, wherein the second output capacitor has a capacitance different from a capacitance of the first output capacitor.

3. The DCDC converter module according to claim 1, wherein the inductor component is between a plus terminal of the first output capacitor and a plus terminal of the second output capacitor.

4. The DCDC converter module according to claim 3, wherein the inductor component is disposed between a contact point between the plus terminal of the first output capacitor and the output inductor and a contact point between the plus terminal of the second output capacitor and the output end of the circuit section.

5. The DCDC converter module according to claim 1, wherein one of the first output capacitor and the second output capacitor is disposed inside the insulating substrate.

6. The DCDC converter module according to claim 1, wherein the first output capacitor and the second output capacitor are both disposed inside the insulating substrate.

7. The DCDC converter module according to claim 1, wherein:
the first output capacitor is on one of the first surface and the second surface of the insulating substrate, and
the second output capacitor is on another of the first surface and the second surface of the insulating substrate.

8. The DCDC converter module according to claim 3, further comprising a magnetic material in at least part of surroundings of a conductor connected between the plus terminal of the first output capacitor and the plus terminal of the second output capacitor.

9. The DCDC converter module according to claim 1, wherein the current path penetrates inside the second output capacitor.

10. The DCDC converter module according to claim 1, wherein an inductance of the inductor component is smaller than an inductance of the output inductor.

11. The DCDC converter module according to claim 1, wherein the first output capacitor at least partially overlaps the second output capacitor when viewed from the thickness direction.

12. The DCDC converter module according to claim 1, wherein the input end, the switching element, the output inductor, the first output capacitor, a first ground end coupled to the first output capacitor, and a second ground end coupled to the second output capacitor, are all disposed on the first surface of the insulating substrate.

13. The DCDC converter module according to claim 1, wherein the switching element and the output end of the circuit section do not overlap when viewed from the thickness direction.

14. The DCDC converter module according to claim 1, wherein the insulating substrate comprises a plurality of insulating layers, and the second output capacitor is disposed in an inner layer of the plurality of insulating layers.

15. A DCDC converter module comprising:
an insulating substrate having a first surface and a second surface that oppose each other in a thickness direction; and
a circuit section that includes a switching element on the first surface of the insulating substrate and an output filter connected in series to the switching element,
wherein the output filter includes an inductor, a first capacitor connected in series to the inductor and a second capacitor connected in series to the inductor and in parallel to the first capacitor,
wherein the first and second output capacitors are disposed at different positions from each other in the thickness direction of the insulating substrate, and
wherein an inductor component is between the first output capacitor and the second output capacitor.

16. The DCDC converter module according to claim 15, wherein:
the output filter is connected in series to the switching element from an input end of the circuit section to an output end of the circuit section,
the second capacitor is disposed at a position closer to a side of the output end of the circuit section than the first capacitor, and
a current path from the switching element to the output end of the circuit section extends through the insulating substrate from the first surface to the second surface.

17. The DCDC converter module according to claim 15, wherein the second capacitor has a capacitance different from a capacitance of the first capacitor.

18. The DCDC converter module according to claim 15, wherein one of the first capacitor and the second capacitor is disposed inside the insulating substrate.

19. The DCDC converter module according to claim 15, wherein an inductance of the inductor component is smaller than an inductance of the inductor.

20. The DCDC converter module according to claim 15, wherein the first capacitor at least partially overlaps the second capacitor when viewed from the thickness direction.
